(19) United States
(12) Patent Application Publication
(10) Pub. No.: US 2015/0357410 A1
(43) Pub. Date: Dec. 10, 2015

(54) SEMICONDUCTOR DEVICE AND MANUFACTURING METHOD OF SEMICONDUCTOR DEVICE

(71) Applicant: Kabushiki Kaisha Toshiba, Minato-ku (JP)

(72) Inventors: Takuya MIZUTANI, Yokkaichi (JP); Yuji SETTA, Kuwana (JP); Kentaro MATSUNAGA, Yokkaichi (JP)

(73) Assignee: Kabushiki Kaisha Toshiba, Minato-ku (JP)

(21) Appl. No.: 14/482,467

(22) Filed: Sep. 10, 2014

(30) Foreign Application Priority Data
Jun. 10, 2014 (JP) 2014-119537

(51) Int. Cl. H01L 29/06; H01L 21/3213; H01L 27/115

(52) U.S. Cl. CPC H01L 29/0657; H01L 27/11582; H01L 21/32139

(57) ABSTRACT

According to one embodiment, it includes an object film and an opening that is formed in the object film and in which a second taper adjoining a first taper is provided. A step is provided at the boundary between the first taper and the second taper.

### CROSS-REFERENCE TO RELATED APPLICATIONS

This application is based upon and claims the benefit of priority from Japanese Patent Application No. 2014-119537, filed on Jun. 10, 2014; the entire contents of which are incorporated herein by reference.

### FIELD

Embodiments described herein relate to a semiconductor device and a manufacturing method of the semiconductor device.

### BACKGROUND

In order to achieve higher integration of nonvolatile semiconductor storage devices, memory cells are often arranged in a three-dimensional manner. In this case, for further efficient stacking process of the memory cells, it is demanded to increase the aspect ratio of the hole pattern.

### BRIEF DESCRIPTION OF THE DRAWINGS

FIG. 1A is a sectional view illustrating a manufacturing method of a semiconductor device according to a first embodiment and FIG. 1B represents plane views cut along line a-a′, line b-b′, line c-c′, and line d-d′ of FIG. 1A;

FIG. 2A is a sectional view illustrating the manufacturing method of the semiconductor device according to the first embodiment, FIG. 2B represents plane views cut along line a-a′, line b-b′, line c-c′, and line d-d′ of FIG. 2A, FIG. 2C is a sectional view illustrating a case where an opening of an object film has a tapered shape, and FIG. 2D is a sectional view illustrating a case where the opening of the object film has a bowing shape;

FIG. 3A is a sectional view illustrating the manufacturing method of the semiconductor device according to the first embodiment and FIG. 3B represents plane views cut along line a-a′, line b-b′, line c-c′, and line d-d′ of FIG. 3A;

FIG. 4A is a sectional view illustrating the manufacturing method of the semiconductor device according to the first embodiment and FIG. 4B represents plane views cut along line a-a′, line b-b′, line c-c′, and line d-d′ of FIG. 4A;

FIG. 5A is a sectional view illustrating the manufacturing method of the semiconductor device according to the first embodiment and FIG. 5B represents plane views cut along line a-a′, line b-b′, line c-c′, and line d-d′ of FIG. 5A;

FIG. 6A is a sectional view illustrating the manufacturing method of the semiconductor device according to the first embodiment and FIG. 6B represents plane views cut along line a-a′, line b-b′, line c-c′, and line d-d′ of FIG. 6A;

FIG. 7A is a sectional view illustrating the manufacturing method of the semiconductor device according to the first embodiment and FIG. 7B represents plane views cut along line a-a′, line b-b′, line c-c′, and line d-d′ of FIG. 7A;

FIG. 8A is a sectional view illustrating the manufacturing method of the semiconductor device according to the first embodiment and FIG. 8B represents plane views cut along line b-b′, line c-c′, and line d-d′ of FIG. 8A;

FIG. 9A is a plane view illustrating a general configuration of a mask member according to the first embodiment, FIG. 9B is a sectional view cut along line a-a′ of FIG. 9A, FIG. 9C is a sectional view cut along line e-e′ of FIG. 9A, and FIG. 9D is a sectional view cut along line f-f′ of FIG. 9A;

FIG. 10A to FIG. 10E are sectional views illustrating a manufacturing method of a semiconductor device according to a second embodiment;

FIG. 11A to FIG. 11D are sectional views illustrating a manufacturing method of a semiconductor device according to a third embodiment;

FIG. 12A to FIG. 12C are sectional views illustrating a manufacturing method of a semiconductor device according to a fourth embodiment;

FIG. 13A to FIG. 13C are sectional views illustrating the manufacturing method of the semiconductor device according to the fourth embodiment;

FIG. 14A to FIG. 14C are sectional views illustrating the manufacturing method of the semiconductor device according to the fourth embodiment;

FIG. 15A to FIG. 15C are sectional views illustrating a manufacturing method of a semiconductor device according to a fifth embodiment;

FIG. 16A to FIG. 16C are sectional views illustrating the manufacturing method of the semiconductor device according to the fifth embodiment;

FIG. 17A to FIG. 17C are sectional views illustrating the manufacturing method of the semiconductor device according to the fifth embodiment; and

FIG. 18 is a perspective view illustrating a general configuration of a semiconductor device according to a sixth embodiment.

### DETAILED DESCRIPTION

According to one embodiment, it includes an object film and an opening that is formed in the object film and in which a second taper adjoining a first taper is provided. A step is provided at the boundary between the first taper and the second taper.

Embodiments of the semiconductor device and a manufacturing method thereof will be described below in detail with reference to the accompanying drawings. The present invention is not limited to the following embodiments.

### First Embodiment

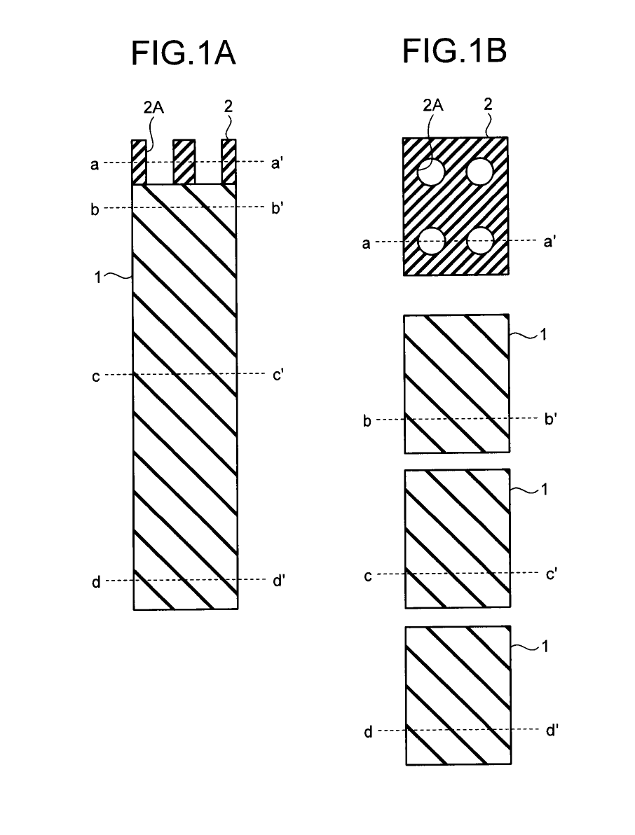

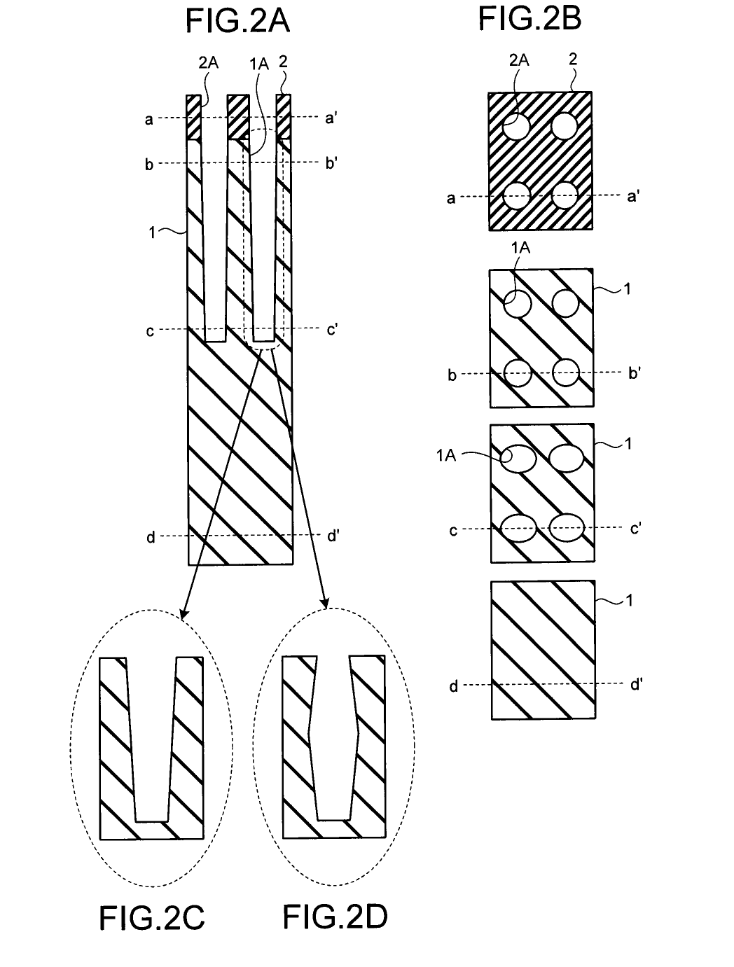

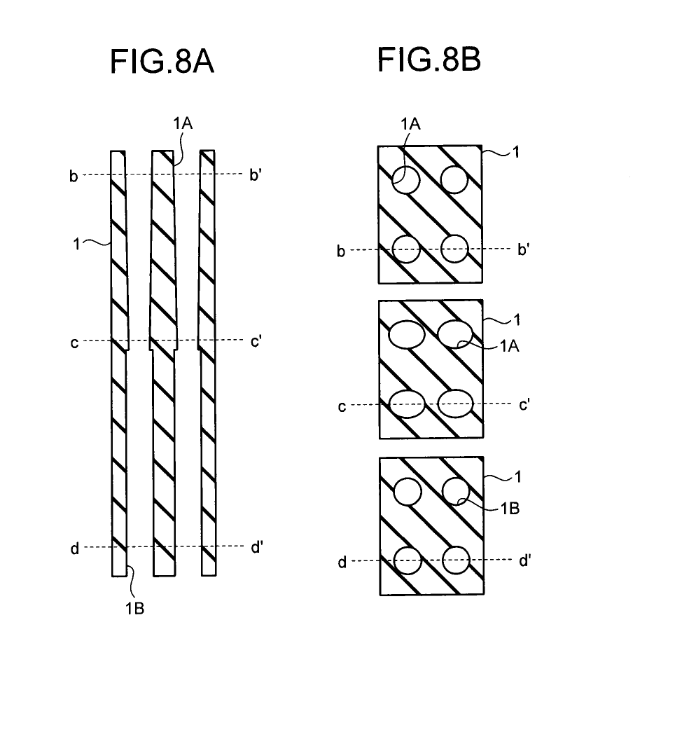

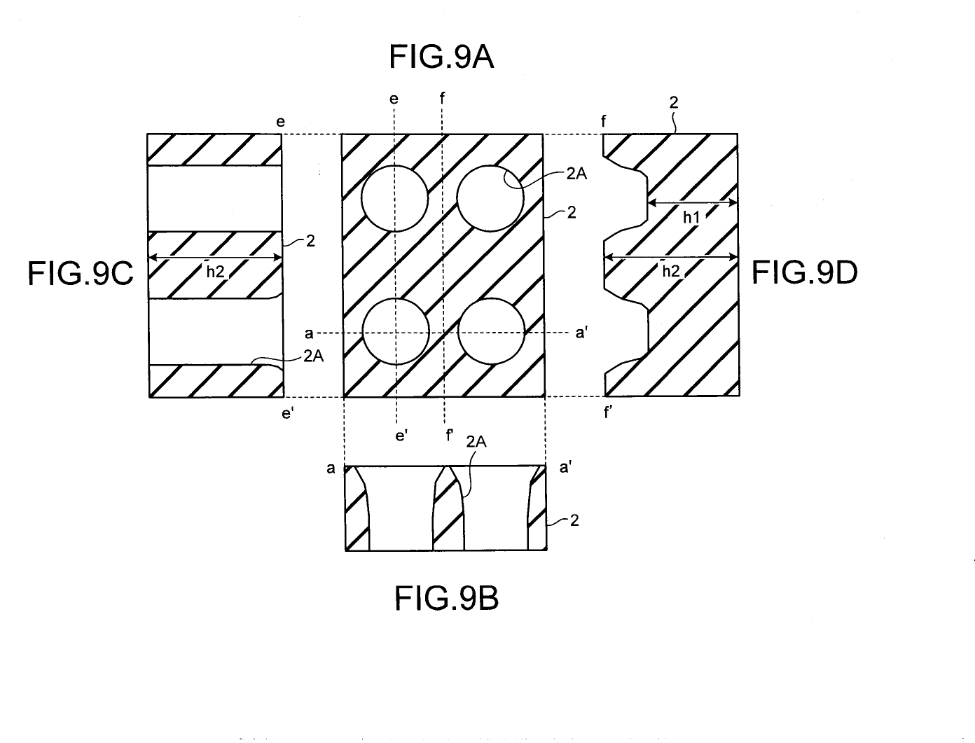

FIG. 1A to FIG. 8A are sectional views illustrating the manufacturing method of the semiconductor device of a first embodiment, FIG. 1B to FIG. 7B are plane views cut along line a-a′, line b-b′, line c-c′, and line d-d′ of FIG. 1A to FIG. 7A, and FIG. 8B represents plane views cut along line b-b′, line c-c′ and line d-d′ of FIG. 8A. Further, FIG. 2C is a sectional view illustrating a case where an opening of an object film has a tapered shape and FIG. 2D is a sectional view illustrating a case where the opening of the object film has a bowing shape. Further, FIG. 9A is a plane view illustrating a general configuration of a mask member according to the first embodiment, FIG. 9B is a sectional view cut along line a-a′ of FIG. 9A, FIG. 9C is a sectional view cut along line e-e′ of FIG. 9A, and FIG. 9D is a sectional view cut along line f-f′ of FIG. 9A.

In FIG. 1A and FIG. 1B, a mask member 2 is formed on an object film 1. It is noted that the object film 1 may be an insulator such as a silicon oxide film or may be a semiconductor such as silicon. The mask member 2 may be a resist film, or may be a hard mask such as a silicon oxide film, a silicon nitride film, a polycrystalline silicon film, or the like. When the mask member 2 is the resist film, openings 2A are formed in the mask member 2 by using a photolithography technique. When the mask member 2 is the hard mask, the openings 2A can be formed in the mask member 2 by using a photolithography technique and a dry etching technique.

Next, as illustrated in FIG. 2A and FIG. 2B, openings 1A are formed in the object film 1 by etching the object film 1 via the mask member 2 having the openings 2A. Here, as illustrated in FIG. 9A to FIG. 9d, the film thickness of the mask member 2 is denoted as h2 and the mask member 2 is etched at the etching of the object film 1. Thus, in the part where the gap between the openings 2A is narrow, the film thickness of the mask member 2 is h1 that is smaller than h2. Then, the thinned film thickness of the mask member 2 causes the difference in the solid angle of the vertical direction (e-e′) and the lateral direction (a-a′), which causes the difference in the amount of entry of the etching gas. As a result, as illustrated in FIG. 2B, the deeper part (the line c-c′) of the opening 1A has a larger flattening of the opening 1A than the shallower part (the line b-b′) of the opening 1A.

Further, when an anisotropy etching with a high aspect ratio is applied, the reaction product generated at the etching is attached to the side wall, so that the lateral etching can be prevented. In addition, since there is a variation in the entry angle of the etching gas, the increased aspect ratio results in an increased frequency of the ion reflections at the side wall of the mask member 2 and/or the object film 1. Thus, the excessive protection effect of the side wall by the reaction product causes the tapered shape in the opening 1A, as illustrated in FIG. 2C. In contrast, the shortage of the protection effect of the side wall results in the insufficient protection of the side etching of the opening 1A, which causes the bowing shape in the opening 1A as illustrated in FIG. 2D.

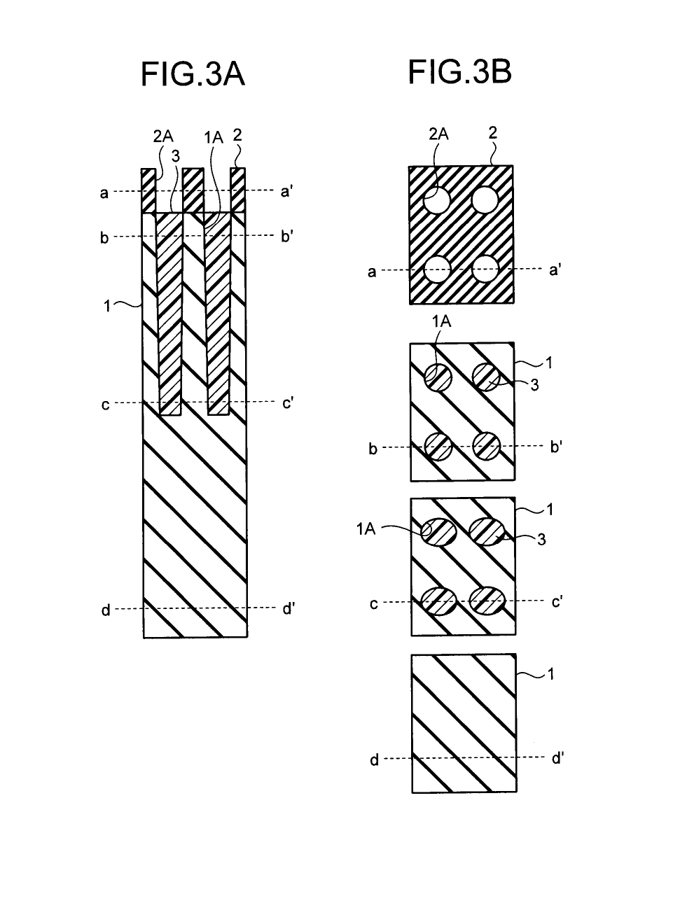

Next, as illustrated in FIG. 3A and FIG. 3B, a self-assembly films 3 is embedded in the openings 2A by a process such as a coating. The self-assembly film 3 can be used for a direct self-assembly. For the self-assembly film 3, a polymer blend-type material that is a mixture of a non-polar polymer 3A and a polar polymer 3B may be employed. For the self-assembly film 3, a polymer blend-type material that is a mixture of a polar polymer and a less polar polymer may be employed. Alternatively, for the self-assembly film 3, a block copolymer-type material such as a block copolymer of polystyrene (PS) and polymethyl methacrylate (PMMA) may be employed, for example.

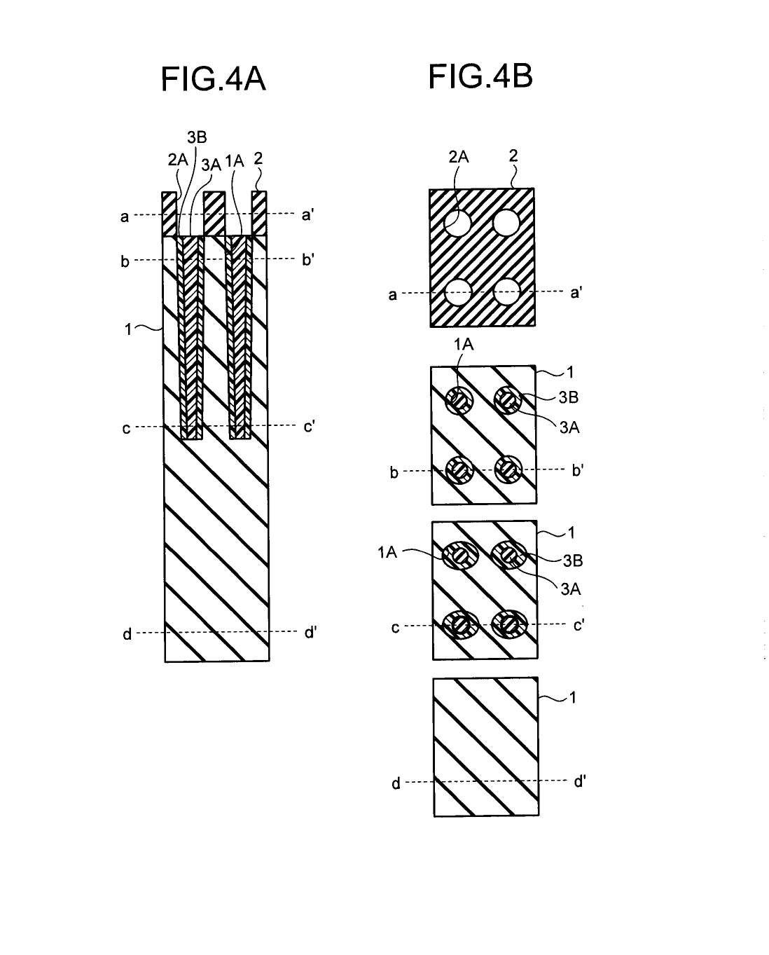

Next, as illustrated in FIG. 4A and FIG. 4B, the self-assembly film 3 is microphase-separated into a non-polar polymer 3A and a polar polymer 3B by a process such as a heat treatment. At this time, the inner wall of each opening 2A is covered with the polar polymer 3B, and the non-polar polymer 3A is arranged vertically inside the polar polymer 3B. Further, the opening 2A can be reshaped to the perfect circle by a pattern that is self-formed by the self-assembly film 3. At this time, having been chemically polarized, the polar polymer 3B has a cylindrical shape that is vertically in the depth direction of the opening 1A.

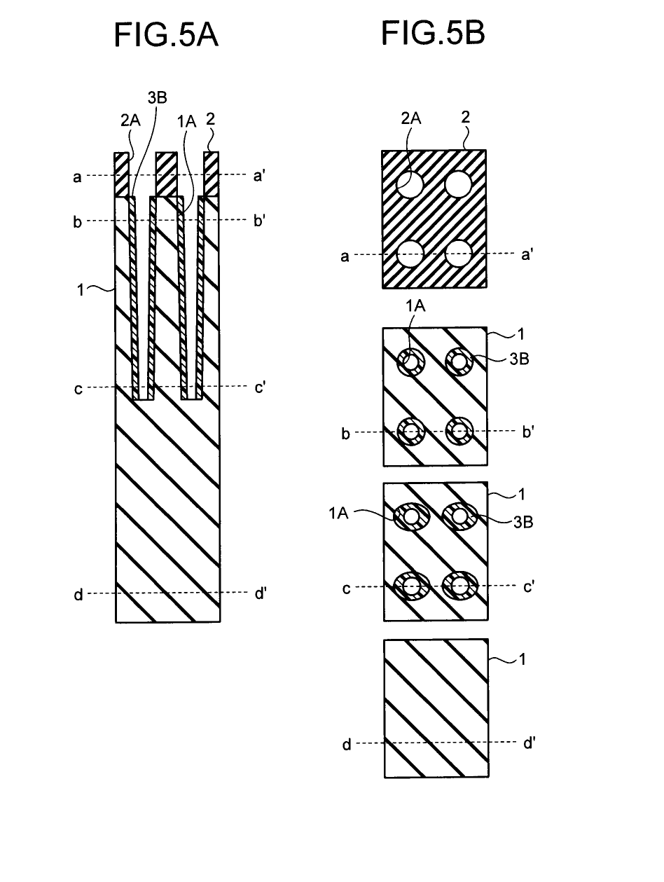

Next, as illustrated in FIG. 5A and FIG. 5B, the non-polar polymer 3A is removed by a process such as a developing. In this case, an organic solvent such as the TMAH can be used as a developer. It is noted that the developing may be a dry developing such as with the oxygen plasma.

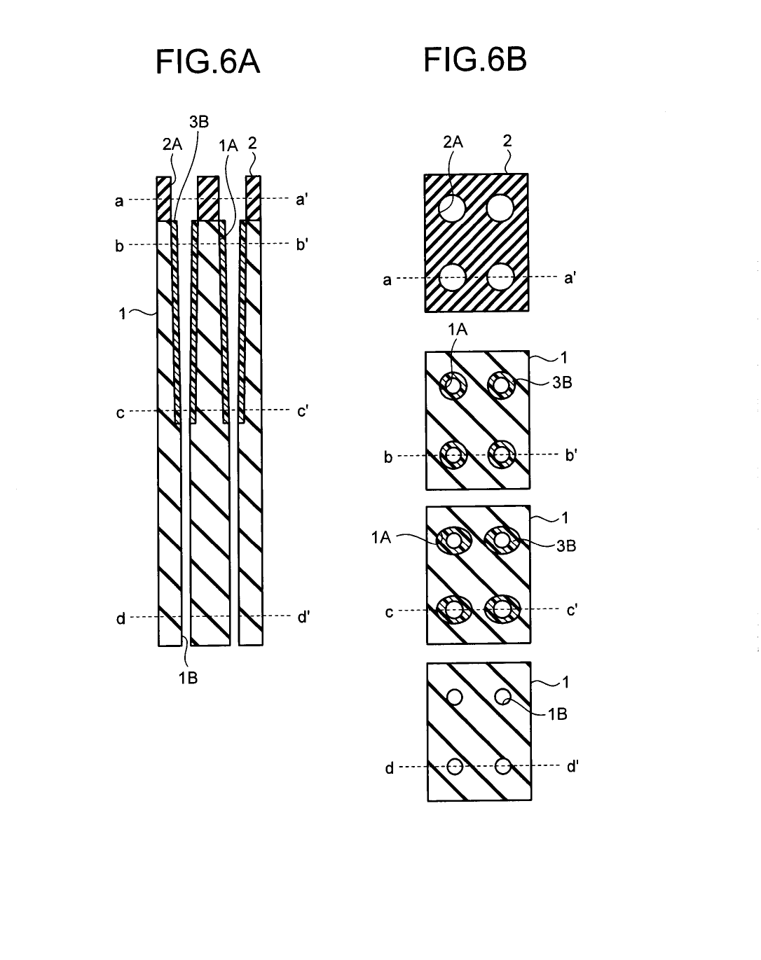

Next, as illustrated in FIG. 6A and FIG. 6B, openings 1B adjoining the openings 1A in the depth direction are formed by etching the object film 1 via each opening 1A whose inner wall is covered with the polar polymer 3B.

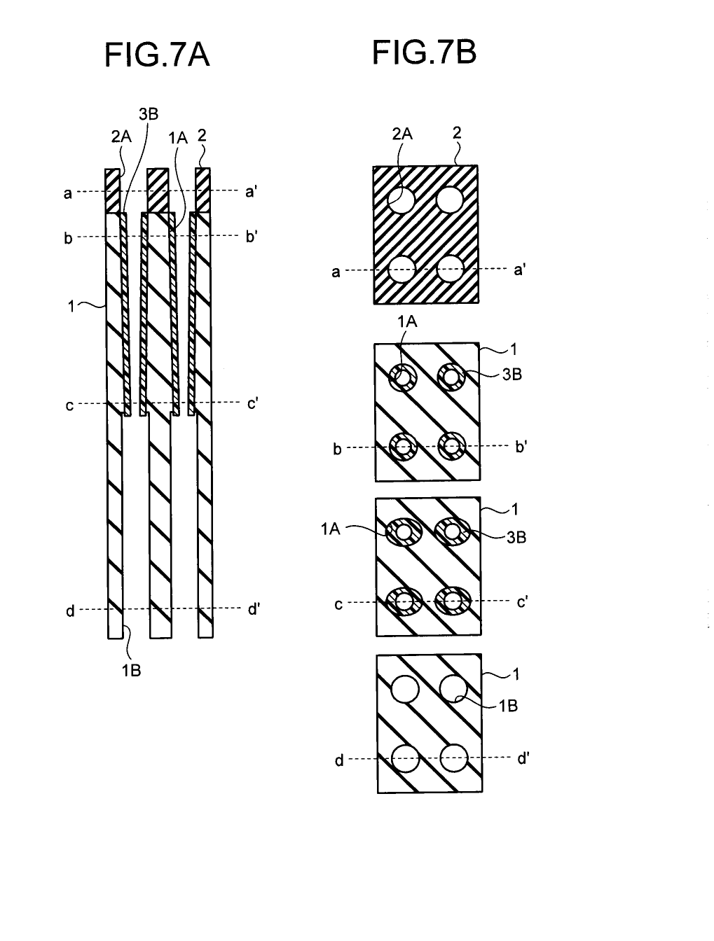

Next, as illustrated in FIG. 7A and FIG. 7B, each opening 1B is expended in the lateral direction by side-etching the opening 1B via each opening 1A whose inner wall is covered with the polar polymer 3B. At this time, the diameter of the opening 1B can be close to the diameter of the opening 1A by the side etching of the opening 1B.

Next, as illustrated in FIG. 8A and FIG. 8B, the mask member 2 and the polar polymer 3B are removed.

Here, the opening 1B is formed in the object film 1 via each opening 1A whose inner wall is covered with the polar polymer 3B, so that the openings 1A can be prevented from being etched when the opening 1B is formed, which allows for the suppression of the degeneration of the shape of the openings 1A and 1B, compared to the method in which the openings 1A and 1B are formed by the same etching process. Further, the opening 1A can be reshaped to the perfect circle by the pattern that has been self-formed by the self-assembly film 3, so that the degeneration in the shape of the opening 1B which would otherwise be caused by the degeneration of the shape of the opening 1A can be suppressed.

### Second Embodiment

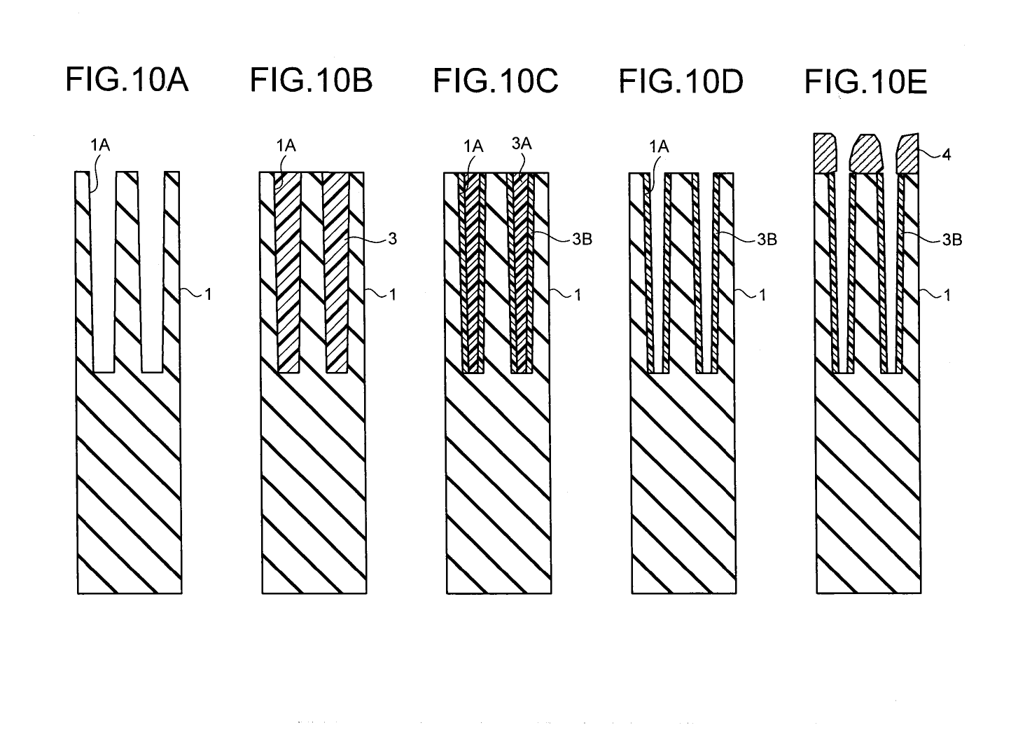

FIG. 10A to FIG. 10E are sectional views illustrating a manufacturing method of a semiconductor device according to a second embodiment.

While description has been provided for the method in which the openings 2A are formed with the mask member 2 remaining after the formation of the openings 1A in the above-described first embodiment, the mask member 2 may be removed after the formation of the openings 1A as illustrated in FIG. 10A. Then, as illustrated in FIG. 10B to FIG. 10D, the polar polymer 3B is formed to the inner wall of each opening 2A. Next, as illustrated in FIG. 10E, a mask member 4 is formed on the object film 1 by a process such as the CVD. In this case, in order to prevent the mask member 4 from being buried in the openings 1A, a deposition condition of a poor coverage can be set. Next, the openings 2A are formed in the object film 1 similarly to the process of FIG. 6A to FIG. 8A.

Here, the mask member 2 is removed after the openings 1A are formed and a mask member 4 is reattached, which can prevent the difference in the residual film thickness of the mask member 2 from affecting the subsequent process.

### Third Embodiment

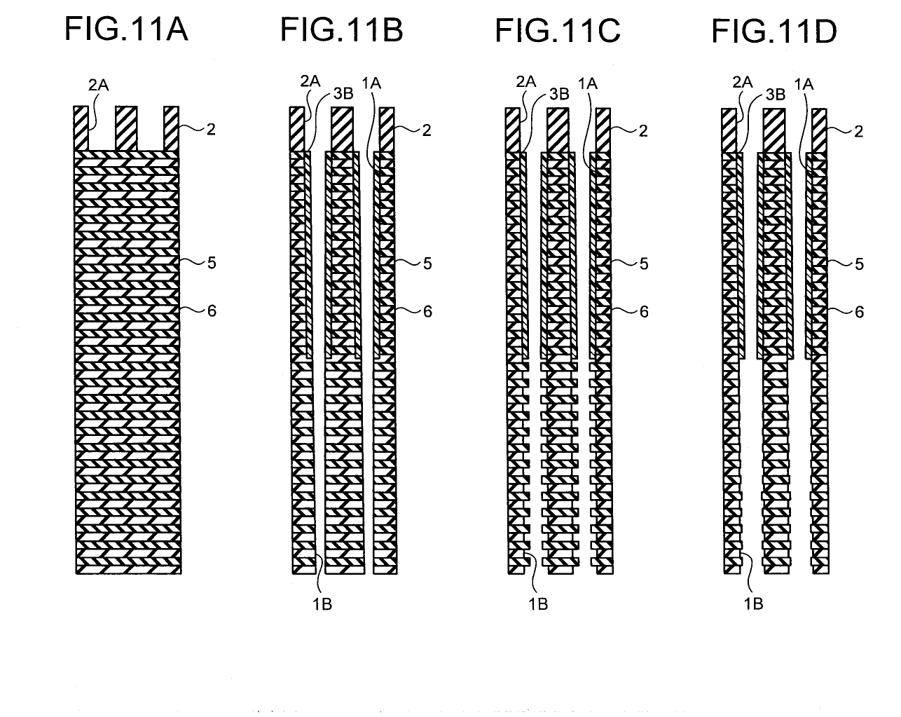

FIG. 11A to FIG. 11D are sectional views illustrating a manufacturing method of a semiconductor device according to a third embodiment.

While description has been provided for the case where the simple substance member is used as the object film 1 in the above-described first embodiment, a composite member may be used as the object film 1 as illustrated in FIG. 11A to FIG. 11D. For example, a stacked structure of a semiconductor 5 and an insulator 6 may be used as the object film 1. A stacked structure of a metal and an insulator, a silicide and an insulator, or a sacrificial layer and an insulator may be used as the object film 1. In this case, as illustrated in FIG. 11C and FIG. 11D, the side etching can be applied under the conditions suitable for the semiconductor 5 and the insulator 6. It is noted that, other than the stacked structure of the semiconductor 5 and the insulator 6, a stacked structure of the different semiconductors having the different etching rate may be used, and a stacked structure of the different semiconductors having the different impurity concentration may be used as the object film 1. The stacked structure of the different semiconductors may be a stacked structure of Si and SiGe, for example. The stacked structure of the semiconductors having the different impurity concentration may be a stacked structure of non-doped Si and doped Si, for example.

### Fourth Embodiment

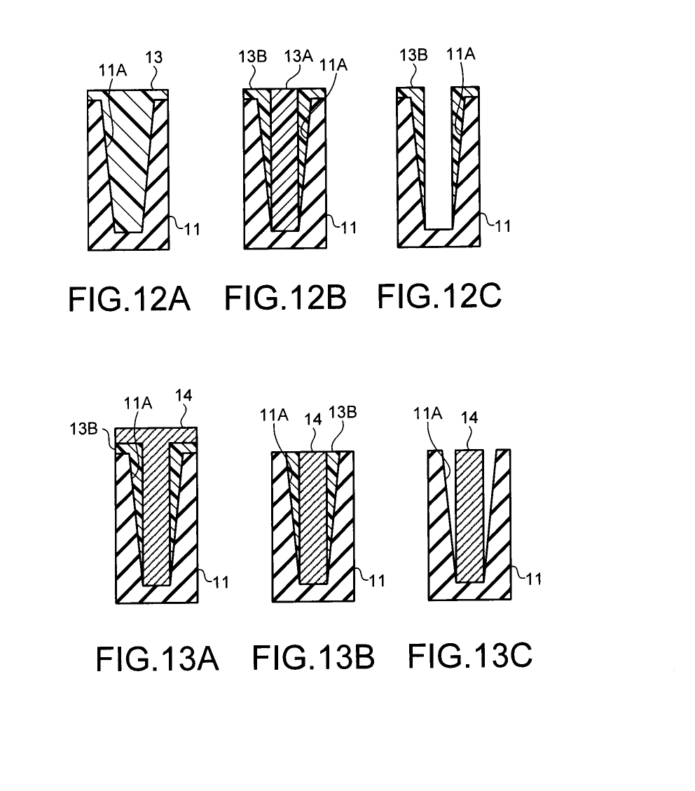

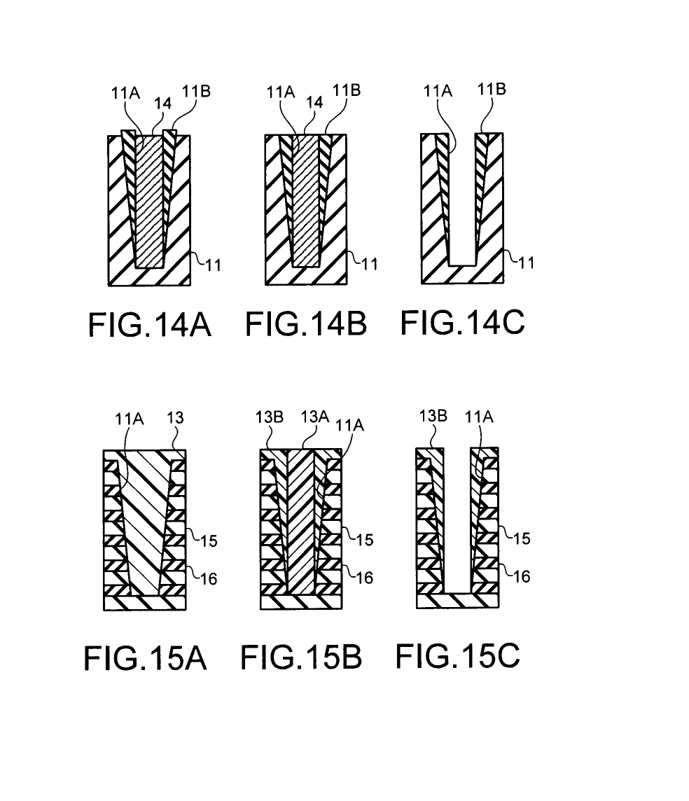

FIG. 12A to FIG. 12C, FIG. 13A to FIG. 13C, and FIG. 14A to FIG. 14C are sectional views illustrating a manufacturing method of a semiconductor device according to a fourth embodiment.

In FIG. 12A, an opening 11A is formed in an object film 11. In this case, it is assumed that the opening 11A has a tapered shape. It is noted that the object film 11 may be an insulator such as a silicon oxide film, or may be a semiconductor such as silicon. A self-assembly film 13 is then embedded in the opening 11A by a process such as a coating.

Next, as illustrated in FIG. 12B, the self-assembly film 13 is microphase-separated into a non-polar polymer 13A and a polar polymer 13B by a process such as a heat treatment. At this time, the inner wall of the opening 11A is covered with the polar polymer 13B, and the non-polar polymer 13A is arranged vertically inside the polar polymer 13B.

Next, as illustrated in FIG. 12C, the non-polar polymer 13A is removed by a process such as a developing. In this case, an organic solvent such as the TMAH can be used as a developer. It is noted that the developing may be a dry developing such as with the oxygen plasma.

Next, as illustrated in FIG. 13A, a core member 14 is embedded in the opening 11A whose inner wall is covered with the polar polymer 13B. It is noted that a coating metal can be used as the material of the core member 14, for example.

Next, as illustrated in FIG. 13B, the core member 14 is reshaped into a thin film by a process such as the CMP to expose the surface of the polar polymer 13B. As illustrated in FIG. 13C, the polar polymer 13B is then removed by a process such as an ashing.

Next, as illustrated in FIG. 14A, a molding member 11B is embedded in a wedge shape into the region from which the polar polymer 13B has been removed. It is noted that, when the object film 11 is the silicon oxide film, the molding member 11B can be formed by a process such as the chemical vapor deposition (CVD).

Next, as illustrated in FIG. 14B, the molding member 11B is reshaped into a thin film by a process such as the CMP to flatten the molding member 11B. As illustrated in FIG. 14C, the core member 14 is then removed by a process such as a wet etching or a dry etching.

Therefore, the opening 11A can be formed such that its depth direction corresponds to the vertical direction even when the opening 11A has the tapered shape, which allows for the proper shape of the opening 11A. Further, the roundness of the opening 11A can be close to 1 even when the opening 11A has the aspect ratio of 2 or greater.

### Fifth Embodiment

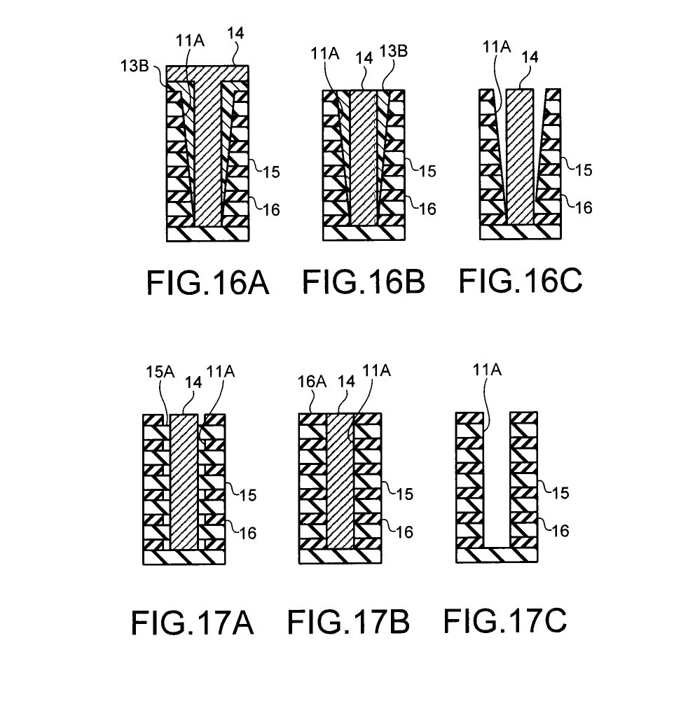

FIG. 15A to FIG. 15C, FIG. 16A to FIG. 16C, and FIG. 17A to FIG. 17C are sectional views illustrating a manufacturing method of a semiconductor device according to a fifth embodiment.

In FIG. 15A, a stacked structure of a semiconductor 15 and an insulator 16 as the object film 11 of FIG. 12A is employed in the present embodiment. Then, the opening 11A is formed in the stacked structure of the semiconductor 15 and the insulator 16. The self-assembly film 13 is embedded in the opening 11A by a process such as a coating.

Next, as illustrated in FIG. 15B, the self-assembly film 13 is microphase-separated into the non-polar polymer 13A and the polar polymer 13B by a process such as a heat treatment. At this time, the inner wall of the opening 11A is covered with the polar polymer 13B, and the non-polar polymer 13A is arranged vertically inside the polar polymer 13B. As illustrated in FIG. 15C, the non-polar polymer 13A is then removed by a process such as a developing.

Next, as illustrated in FIG. 16A, the core member 14 is embedded in the opening 11A whose inner wall is covered with the polar polymer 13B. As illustrated in FIG. 16B, the core member 14 is then reshaped into a thin film by a process such as the CMP to expose the surface of the polar polymer 13B. As illustrated in FIG. 16C, the polar polymer 13B is then removed by a process such as an ashing.

Next, as illustrated in FIG. 17A, in the region from which the polar polymer 13B has been removed, a semiconductor 15A is grown from the semiconductor 15 as a seed layer in an epitaxial manner. Furthermore, as illustrated in FIG. 17B, the insulator 16 is oxidized to form an insulator 16A in the region from which the polar polymer 13B has been removed. The semiconductor 15A and the insulator 16A can be shaped such that the opening 11A is vertical in the depth direction. As illustrated in FIG. 17C, the core member 14 is then removed by a process such as a wet etching or a dry etching.

Therefore, the opening 11A having a tapered shape can be shaped to be vertical in the depth direction even when the stacked structure of the semiconductor 15 and the insulator 16 is employed as the object film 11, which allows for the proper shape of the opening 11A.

### Sixth Embodiment

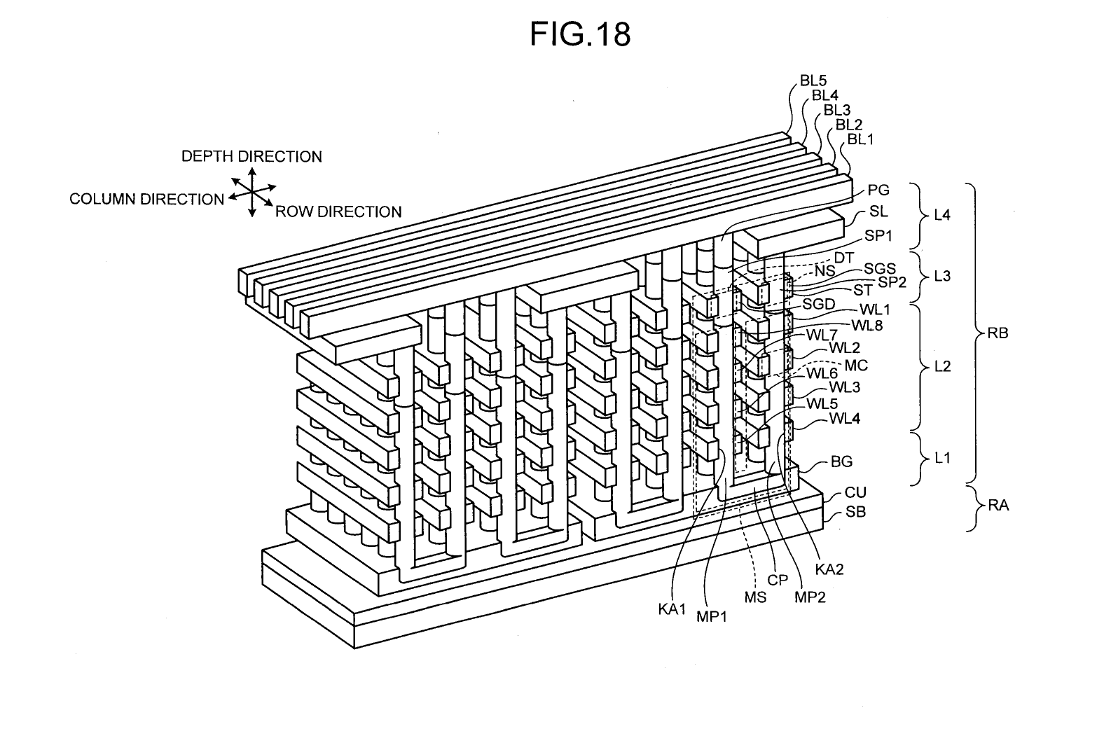

FIG. 18 is a perspective view illustrating a general configuration of a semiconductor device according to a sixth embodiment. It is noted that, in FIG. 18, a memory cell array of a three-dimensional NAND flash memory is exemplified as the semiconductor device.

In FIG. 18, the memory cell array has a circuit region RA and a memory region RB. The circuit region RA is formed in a semiconductor substrate SB. The memory region RB is formed on the circuit region RA.

The memory cell array has a circuit layer CU, a back gate transistor layer L1, a memory cell transistor layer L2, a selection transistor layer L3, and a wiring layer L4 that are formed in the order on the semiconductor substrate SB.

The back gate transistor layer L1 functions as back gate transistors. The memory cell transistor layer L2 functions as cell transistors of memory cells MC. The selection transistor layer L3 functions as select transistors ST and DT. The wiring layer L4 functions as source lines SL and bit lines BL1 to BL5.

The back gate transistor layer L1 has a back gate layer BG. The back gate layer BG is formed so as to expand two-dimensionally in a row direction and a column direction that are parallel to the semiconductor substrate SB. The back gate layer BG is formed by polycrystal silicon, for example.

Further, the back gate layer BG has back gate holes. Each back gate hole is formed so as to carve the back gate layer BG. Each back gate hole is formed in substantially a square whose longitudinal direction is the column direction when viewed from the top. A connection layer CP is formed in the back gate hole.

The memory cell transistor layer L2 is formed on the back gate transistor layer L1. The memory cell transistor layer L2 has word lines WL1 to WL8. The word lines WL1 to WL8 interpose interlayer insulating layer and is stacked interposing the interlayer insulating layer. The word lines WL1 to WL8 are formed in a stripe manner extending in the row direction with a predetermined pitch in the column direction. The word lines WL1 to WL8 are formed by polycrystal silicon, tungsten, or NiSi for example.

Further, the memory cell transistor layer L2 has memory holes KA1 and KA2. The memory holes KA1 and KA2 are formed so as to penetrate the word lines WL1 to WL8. The memory holes KA1 and KA2 are formed so as to be aligned adjacently the ends in the column direction of the back gate hole. The cell transistors of the memory cell MC are connected in series in the stack direction and connected so as to turn back in the stack direction via a connection layer CP, and thus a memory string MS is configured.

The selection transistor layer L3 has select gate lines SGS and SGD. The select gate lines SGS and SGD are formed in a stripe manner extending in the row direction so as to have a predetermined pitch in the column direction. A pair of the select gate lines SGS and a pair of the select gate lines SGD are arranged alternately in the column direction. The select gate lines SGS are formed in the upper layer of one pillar portion MP2, while the select gate lines SGD are formed in the upper layer of the other pillar portion MP1. The select gate lines SGS and SGD are formed by polycrystal silicon.

The selection transistor layer L3 has pillar portions SP1 and SP2. The pillar portions SP1 and SP2 penetrate the select gate lines SGS and SGD, respectively. Further, the pillar portion SP1 and SP2 are stacked so as to be adjusted with respect to the pillar portions MP1 and MP2, respectively. The select transistors ST and DT are connected in series to both ends of the memory string MS, and thus a NAND string NS is configured.

The wiring layer L4 is formed in the upper layer on the selection transistor layer L3. The wiring layer L4 has source lines SL, plugs PG, and bit lines BL1 to BL5.

Each source line SL is formed in a plate shape extending in the row direction. The source line SL is formed so as to contact with the upper surface of the pair of the select gate lines SGS neighboring in the column direction. The plug PG is formed so as to contact with the upper surface of the select gate line SGD and extend in the vertical direction with respect to the surface of the semiconductor substrate SB. The bit lines BL1 to BL5 are formed in a stripe manner extending in the column direction with a predetermined pitch in the row direction. The bit lines BL1 to BL5 are formed so as to contact with the upper surface of the plug PG. The source line SL, the plug PG, and the bit lines BL1 to BL5 are formed by a metal such as tungsten (W), for example.

It is noted that the memory holes KA1 and KA2 may be formed by the process similar to FIG. 11A to FIG. 11D, or may be formed by the process similar to FIG. 15A to FIG. 15C, FIG. 16A to FIG. 16C, and FIG. 17A to FIG. 17C. In this case, the semiconductor 5, 15 can be used for the word lines WL1 to WL8, and the insulator 6, 16 can be used for the interlayer insulating layer among the word lines WL1 to WL8.

Therefore, the aspect ratio of the memory holes KA1 and KA2 can be increased while the degeneration of the shape of the memory holes KA1 and KA2 is suppressed. This allows for the increased number of stacks of the word lines WL1 to WL8, so that the integration of the three-dimensional NAND flash memory can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising an opening in which a first tapered shape and a second tapered shape adjoining the first tapered shape in a depth direction are provided in a process of a hole having an aspect of 2 or greater in a manufacturing of a semiconductor device,
wherein flattening (A)≦flattening (C)≦flattening (B) is satisfied for an upper part (A) of the first tapered shape, a boundary part (B) between the first tapered shape and the second tapered shape, and a bottom part (C) of the second tapered shape, where a shorter diameter and a longer diameter of the hole are used to define the flattening as (a longer diameter−a shorter diameter)/the longer diameter.

2. The semiconductor device of claim 1, wherein a step is provided to the boundary part of the first tapered shape and the second tapered shape.

3. The semiconductor device of claim 1, wherein the opening is formed in a stacked structure of a semiconductor and an insulator, a metal and an insulator, a silicide and an insulator, or a sacrificial layer and an insulator.

4. The semiconductor device of claim 3, wherein the semiconductor, the metal, or the silicide is used as a word line of a three-dimensional NAND flash memory.

5. A semiconductor device comprising:
an opening formed in an object film and formed with a tapered shape in a depth direction; and
a molding layer formed in a wedge shape in an inner wall of the opening so that the opening is vertical in the depth direction.

6. The semiconductor device of claim 5, wherein the object film and the molding layer are made of the same material.

7. The semiconductor device of claim 6, wherein the object film is of a stacked structure of a semiconductor and an insulator, a metal and an insulator, a silicide and an insulator, or a sacrificial layer and an insulator.

8. The semiconductor device of claim 7, wherein the semiconductor, the metal, or the silicide is used as a word line of a three-dimensional NAND flash memory.

9. A manufacturing method of a semiconductor device, the manufacturing method comprising:
forming a first opening of an object film;
embedding a self-assembly film in the first opening;
separating the self-assembly film into a first polymer component covering an inner wall of the first opening and a second polymer component arranged inside the first polymer component;
removing the second polymer component;
forming in the object film a second opening adjoining the first opening in a depth direction via the first opening whose inner wall is covered with the first polymer component; and
side-etching the second opening with the first polymer component being a side wall protection film of the first opening.

10. The manufacturing method of the semiconductor device of claim 9, wherein the second polymer component is formed in a cylindrical shape that is vertical in the depth direction of the first opening.

11. The manufacturing method of the semiconductor device of claim 9, wherein the first polymer component is a polar polymer and the second polymer component is a less polar polymer.

12. The manufacturing method of the semiconductor device of claim 9, wherein a first tapered shape is provided in the first opening and a second tapered shape is provided in the second opening, wherein flattening (A)≦flattening (C)≦flattening (B) is satisfied for an upper part (A) of the first tapered shape, a boundary part (B) between the first tapered shape and the second tapered shape, and a bottom part (C) of the second tapered shape.

13. The manufacturing method of the semiconductor device of claim 9, wherein the object film is of a stacked structure of a semiconductor and an insulator, a metal and an insulator, a silicide and an insulator, or a sacrificial layer and an insulator.

14. The manufacturing method of the semiconductor device of claim 13, wherein the semiconductor, the metal, or the silicide is used as a word line of a three-dimensional NAND flash memory.

15. A manufacturing method of a semiconductor device, the manufacturing method comprising:
forming an opening in an object film;
embedding a self-assembly film in the opening;
separating the self-assembly film into a first polymer component covering an inner wall of the opening and a second polymer component arranged inside the first polymer component;
removing the second polymer component;
embedding a core member in a region from which the second polymer component has been removed;
removing the first polymer component between the core member and the opening; and
embedding, in a region from which the first polymer has been removed, a molding member for shaping the opening.

16. The manufacturing method of the semiconductor device of claim 15, wherein the second polymer component is formed vertically.

17. The manufacturing method of the semiconductor device of claim 15, wherein the first polymer component is a polar polymer and the second polymer component is a less polar polymer.

18. The manufacturing method of the semiconductor device of claim 15, wherein the object film and the molding member are made of the same material.

19. The manufacturing method of the semiconductor device of claim 18, wherein the object film is of a stacked structure of a semiconductor and an insulator, a metal and an insulator, a silicide and an insulator, or a sacrificial layer and an insulator.

20. The manufacturing method of the semiconductor device of claim 19, wherein the semiconductor, the metal, or the silicide is used as a word line of a three-dimensional NAND flash memory.
